(19) United States
(12) Patent Application Publication
(10) Pub. No.: US 2023/0301111 A1
(43) Pub. Date: Sep. 21, 2023

(54) SEMICONDUCTOR STORAGE DEVICE AND METHOD OF MANUFACTURING THE SAME

(71) Applicant: Kioxia Corporation, Tokyo (JP)

(72) Inventors: Kenta YAMADA, Yokkaichi Mie (JP); Yosuke MITSUNO, Yokkaichi Mie (JP); Takuya SUZUKI, Kuwana Mie (JP); Katsuyuki KITAMOTO, Yokkaichi Mie (JP); Ken KOMIYA, Nagoya Aichi (JP)

(73) Assignee: Kioxia Corporation, Tokyo (JP)

(21) Appl. No.: 17/941,987

(22) Filed: Sep. 9, 2022

(30) Foreign Application Priority Data
Mar. 18, 2022 (JP) 2022-044447

(51) Int. Cl. H01L 27/11575; H01L 25/065; H01L 25/18; H01L 23/00; H01L 27/11548; H01L 27/11556; H01L 27/11582; H01L 25/00

(52) U.S. Cl. CPC H01L 27/11575; H01L 25/0657; H01L 25/18; H01L 24/08; H01L 27/11548; H01L 27/11556; H01L 27/11582; H01L 24/80; H01L 25/50; H01L 2224/08145; H01L 2224/80895; H01L 2224/80896; H01L 2924/1431; H01L 2924/14511

(57) ABSTRACT

A semiconductor storage device includes a processing circuit provided on a substrate, a plurality of first electrodes connected to the processing circuit, and a plurality of second electrodes connected to the plurality of first electrodes. The semiconductor storage device also includes a memory cell array connected to the plurality of second electrodes. The memory cell array includes a block, and the block includes a string unit. Each string unit includes a plurality of memory cells, and a plurality of column-shaped parts penetrating through at least one stack body that is a stack of a plurality of electrode films between which an insulating film is interposed. The semiconductor storage device includes a slit insulating, for each string unit, a source line electrically connected to a portion of the plurality of memory cells and a source line electrically connected to another portion of the memory cells.

### CROSS-REFERENCE TO RELATED APPLICATIONS

This application is based upon and claims the benefit of priority from the prior Japanese Patent Application No. 2022-044447 filed on Mar. 18, 2022; the entire contents of which are incorporated herein by reference.

### FIELD

Embodiments described herein relate generally to a semiconductor storage device and a method of manufacturing the same.

### BACKGROUND

Faster access performance is requested for a semiconductor storage device.

### BRIEF DESCRIPTION OF THE DRAWINGS

FIG. 1 is a block diagram of a memory system according to a first embodiment;

FIG. 2 is a diagram illustrating a configuration of a block of a memory cell array having a three-dimensional structure according to the first embodiment;

FIG. 3 is a schematic exploded perspective view illustrating a configuration of a semiconductor storage device according to the first embodiment;

FIG. 4 is a cross-sectional view of the semiconductor storage device according to the first embodiment;

FIG. 5 is a schematic cross-sectional view of a column-shaped part of a memory cell part according to the first embodiment;

FIG. 6 is a diagram for description of the position of connection between each wire as an upper layer wire and a source line of each string unit according to the first embodiment;

FIG. 7 is a partial cross-sectional view of the semiconductor storage device according to the first embodiment in a Y direction;

FIG. 8 is a cross-sectional view illustrating a method of manufacturing a memory chip according to the first embodiment;

FIG. 9 is a cross-sectional view illustrating the method of manufacturing the memory chip according to the first embodiment, following FIG. 8;

FIG. 10 is a cross-sectional view illustrating the method of manufacturing the memory chip according to the first embodiment, following FIG. 9;

FIG. 11 is a cross-sectional view illustrating the method of manufacturing the memory chip according to the first embodiment, following FIG. 10;

FIG. 12 is a cross-sectional view illustrating the method of manufacturing the memory chip according to the first embodiment, following FIG. 11;

FIG. 13 is a cross-sectional view illustrating the method of manufacturing the memory chip according to the first embodiment, following FIG. 12;

FIG. 14 is a cross-sectional view illustrating the method of manufacturing the memory chip according to the first embodiment, following FIG. 13;

FIG. 15 is a cross-sectional view illustrating a method of manufacturing a controller chip according to the first embodiment;

FIG. 16 is a cross-sectional view illustrating the method of manufacturing the controller chip according to the first embodiment;

FIG. 17 is a schematic cross-sectional view of a semiconductor storage device according to a modification of the first embodiment;

FIG. 18 is a diagram for description of sectional shapes of slits along an XY plane in an upper layer region and a lower layer region according to the modification of the first embodiment;

FIG. 19 is a schematic diagram illustrating a lower layer region of a stack body according to the modification of the first embodiment;

FIG. 20 is a schematic diagram of the memory chip in a state in which memory holes of the upper layer region are formed above the lower layer region according to the modification of the first embodiment;

FIG. 21 is a schematic diagram of the memory chip in a state in which a plurality of column-shaped parts are formed according to the modification of the first embodiment;

FIG. 22 is a schematic cross-sectional view of the memory chip in a state in which openings of plate-shaped slits are formed in the upper layer region according to the modification of the first embodiment;

FIG. 23 is a schematic cross-sectional view of the memory chip in a state in which sacrifice films are replaced with a conductive material according to the modification of the first embodiment;

FIG. 24 is a schematic diagram for description of a sectional shape of a slit along an XZ plane according to the modification of the first embodiment;

FIG. 25 is a schematic cross-sectional view of the memory chip in a state in which an insulation material is embedded in the slit according to the modification of the first embodiment;

FIG. 26 is a schematic cross-sectional view of the memory chip in a state in which bonding electrodes are formed on a front surface of the memory chip according to the modification of the first embodiment;

FIG. 27 is a schematic cross-sectional view of the semiconductor storage device according to the modification of the first embodiment in a state in which the memory chip and the controller chip are bonded to each other;

FIG. 28 is a schematic cross-sectional view of the semiconductor storage device according to the modification of the first embodiment in a state in which the memory chip from which a substrate part of the memory chip is removed and the controller chip are bonded to each other;

FIG. 29 is a schematic cross-sectional view of the semiconductor storage device according to the modification of the first embodiment in a state in which the memory chip in which two slits are formed and the controller chip are bonded to each other;

FIG. 30 is a plan view of the memory chip at which the two slits are formed according to the modification of the first embodiment when viewed from a back surface side of the memory chip;

FIG. 31 is a cross-sectional view of a semiconductor storage device according to a second embodiment;

FIG. 32 is a diagram illustrating a configuration of one block of a memory cell array having a three-dimensional structure according to the second embodiment;

FIG. 33 is a partial cross-sectional view of the semiconductor storage device according to the second embodiment in the Y direction;

FIG. 34 is a cross-sectional view of a semiconductor storage device according to a third embodiment;

FIG. 35 is a diagram illustrating a configuration of one block of a memory cell array having a three-dimensional structure according to the third embodiment; and

FIG. 36 is a partial cross-sectional view of the semiconductor storage device according to the third embodiment in the Y direction.

### DETAILED DESCRIPTION

A semiconductor storage device according to an embodiment includes: a substrate; a circuit provided on the substrate; a plurality of first electrodes provided above the substrate and connected to the circuit through a plurality of first contacts; a plurality of second electrodes connected to the plurality of first electrodes; a memory cell array connected to the plurality of second electrodes through a plurality of second contacts, the memory cell array including a block, the block including a plurality of units, each of the units including a plurality of memory cell transistors and a plurality of first column-shaped parts, the plurality of first column-shaped parts penetrating through at least one stack body that is a stack of a plurality of electrode layers between which an insulating layer is interposed; a first source region provided above the memory cell array and electrically connected to a portion of the plurality of memory cell transistors; a second source region provided above the memory cell array and electrically connected to another portion of the plurality of memory cell transistors; and a first slit insulating the first source region and the second source region for each of the units.

Embodiments will be described below with reference to the accompanying drawings.

### First Embodiment

### (Configuration of Memory System)

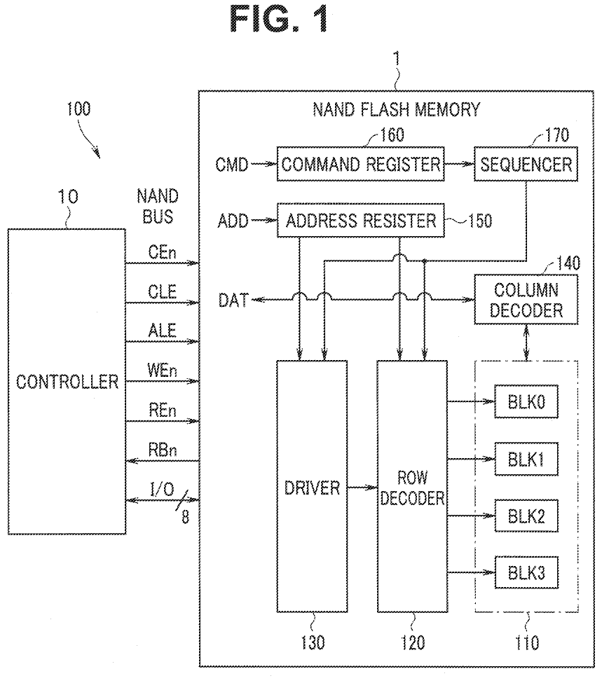

FIG. 1 is a block diagram for description of a configuration of a memory system 100 according to the present embodiment. The memory system 100 includes a semiconductor storage device 1 and a memory controller 10.

The memory controller 10 is connected to the semiconductor storage device 1 through a NAND bus. The NAND bus performs signal transmission and reception in accordance with a NAND interface. The memory controller 10 controls the semiconductor storage device 1.

Signals transmitted and received between the memory controller 10 and the semiconductor storage device 1 through the NAND bus include a chip enable signal CEn, a command latch enable signal CLE, an address latch enable signal ALE, a write enable signal WEn, a read enable signal REn, a ready/busy signal RBn, and input-output signals I/O.

The memory controller 10 is connected to a non-illustrated host device. The memory controller 10 accesses the semiconductor storage device 1 in response to a request received from the host device.

The semiconductor storage device 1 is a NAND flash memory. The semiconductor storage device 1 includes a memory cell array 110 and a peripheral circuit. The peripheral circuit includes a row decoder 120, a driver 130, a column decoder 140, an address register 150, a command register 160, and a sequencer 170.

The memory cell array 110 includes a plurality of memory cells. Each memory cell can store data of one bit or a plurality of bits in a non-volatile manner.

The memory cell array 110 includes a plurality of blocks BLK. The memory cell array 110 is a NAND memory cell array having a three-dimensional structure.

Each block BLK includes a plurality of non-volatile memory cells associated with rows and columns. Four blocks BLK0 to BLK3 are illustrated in FIG. 1. The memory cell array 110 can store data in a non-volatile manner, the data being provided by the memory controller 10.

The sequencer 170 controls operation of the entire semiconductor storage device 1 based on a command CMD temporarily stored in the command register 160.

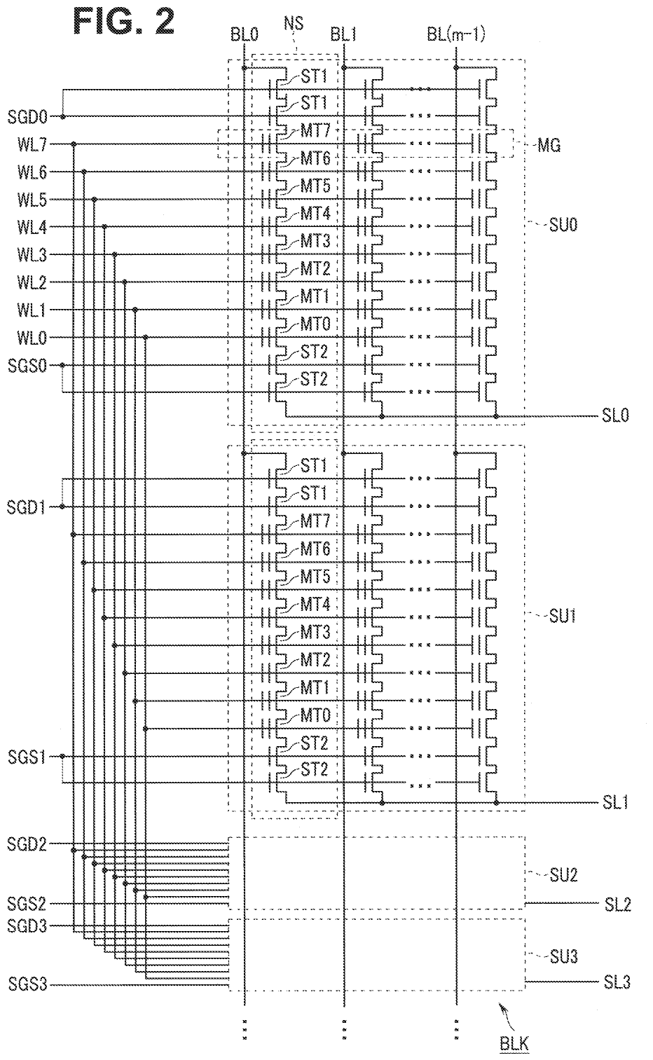

FIG. 2 is a diagram illustrating a configuration of each block BLK of the above-described memory cell array 110 having a three-dimensional structure. FIG. 2 illustrates one of the plurality of blocks BLK. Any other block of the memory cell array 110 has the same configuration as in FIG. 2.

As illustrated, one block BLK includes, for example, four string units SU0 to SU3. Each string unit SU includes a plurality of NAND strings NS. In this example, each of the plurality of NAND strings NS includes eight memory cells MT (MT0 to MT7) and selection transistors ST1 and ST2. Note that the number of memory cells MT included in each NAND string NS is eight in this example but not limited to eight, and may be, for example, 32, 48, 64, 96, or more. The selection transistors ST1 and ST2 are each indicated as one transistor in electric circuit but may be each a memory cell transistor in structure. In this example, a plurality of selection transistors are used as each of the selection transistors ST1 and ST2 to increase a cutoff characteristic.

The memory cells MT are disposed between the selection transistors ST1 and ST2 and connected in series. The memory cell MT7 on one end side is connected to the selection transistor ST1, and the memory cell MT0 on the other end side is connected to the selection transistor ST2.

Gates of the selection transistors ST1 of the string units SU0 to SU3 are connected to selection gate lines SGD0 to SGD3, respectively. Voltages of the selection gate lines SGD0 to SGD3 can be each independently controlled by the sequencer 170.

Gates of the selection transistors ST2 of the string units SU0 to SU3 are connected to selection gate lines SGS0 to SGS3, respectively. Voltages of the selection gate lines SGS0 to SGS3 can be each independently controlled by the sequencer 170. The selection transistor ST2 are selection gates for selecting the plurality of string units SU in the block BLK. A plurality of voltages different from one another can be supplied to the gates of the plurality of selection transistors ST2.

The sources of the selection transistors ST2 of the string units SU0 to SU3 are connected to source lines SL0 to SL3, respectively. Voltages of the source lines SL0 to SL3 can be each independently controlled by the sequencer 170.

Gates of the memory cells MT0 to MT7 in the same block BLK are connected in common to word lines WL0 to WL7, respectively. In other words, gates of memory cells MTi on the same row in the block BLK are connected to the same word line WLi.

In other words, in the same block BLK, the word lines WL0 to WL7 are connected in common among the string units SU0 to SU3, but the selection gate lines SGD0 to SGD3 and SGS0 to SGS3 are independent among the string units SU0 to SU3 in the same block BLK.

Each NAND string NS is connected to a corresponding bit line BL. Thus, each memory cell MT is connected to the bit line BL through the selection transistor ST1, or any other memory cell MT in some cases, included in the NAND string NS.

Data of the memory cells MT in the same block BLK is deleted all at once. Data reading and writing are performed for each a memory cell group MG.

Note that each memory cell MT may be a single level cell (SLC) that can store one bit data or may be a memory cell that can store data of multiple-value bits such as two bits or three bits.

### (Entire Configuration of Semiconductor Storage Device)

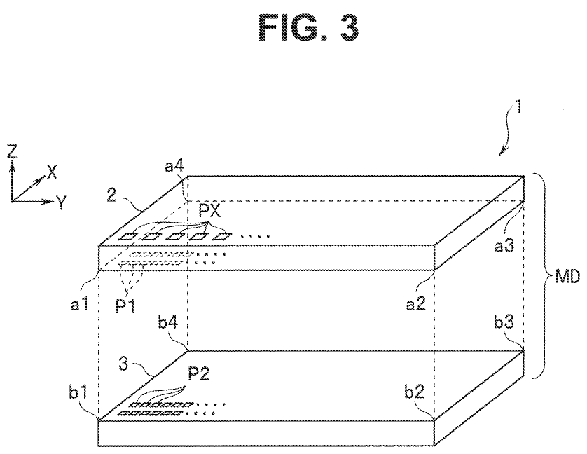

FIG. 3 is a schematic exploded perspective view illustrating a configuration of the semiconductor storage device 1 according to the present embodiment. The semiconductor storage device 1 according to the present embodiment includes a memory chip 2 including a memory cell array, and a controller chip 3 including a peripheral circuit. The memory chip 2 includes the memory cell array 110. The controller chip 3 includes at least a portion of the above-described peripheral circuit.

In FIG. 3, a plurality of bonding pad electrodes PX are provided on an upper surface of the memory chip 2. A plurality of bonding electrodes P1 are provided on a lower surface of the memory chip 2. A plurality of bonding electrodes P2 are provided on an upper surface of the controller chip 3.

The surface of the memory chip 2 on which the plurality of bonding electrodes P1 are provided is referred to as a front surface, and the surface of the memory chip 2 on which the plurality of bonding pad electrodes PX are provided is referred to as a back surface. The surface of the controller chip 3 on which the plurality of bonding electrodes P2 are provided is referred to as a front surface, and a surface opposite the front surface is referred to as a back surface. In the illustrated example, the front surface of the controller chip 3 is provided higher than the back surface of the controller chip 3, and the back surface of the memory chip 2 is provided higher than the front surface of the memory chip 2.

In the semiconductor storage device 1, the front surface of the memory chip 2 and the front surface of the controller chip 3 are oppositely disposed and bonded to each other. The plurality of bonding electrodes P1 are provided in correspondence with the plurality of respective bonding electrodes P2 and disposed at positions where the plurality of bonding electrodes P1 can be bonded to the plurality of bonding electrodes P2. The bonding electrodes P1 and P2 function as electrodes for bonding and electrically connecting the memory chip 2 and the controller chip 3 to each other. The bonding pad electrodes PX function as electrodes for electrically connecting the semiconductor storage device 1 to, for example, a non-illustrated substrate.

In FIG. 3, corners a1, a2, a3, and a4 of the memory chip 2 correspond to respective corners b1, b2, b3, and b4 of the controller chip 3.

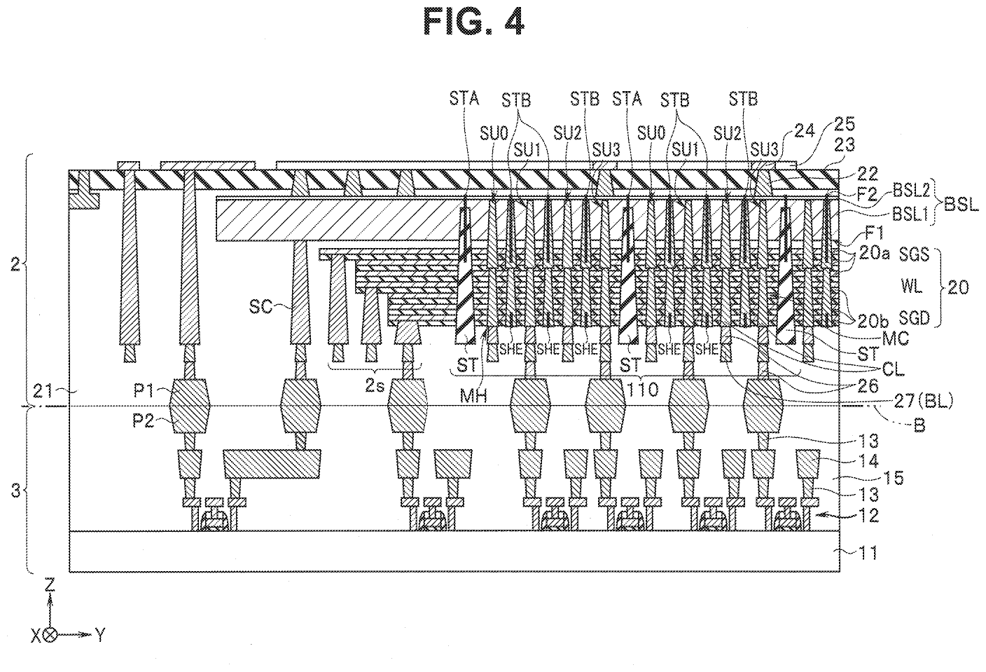

FIG. 4 is a cross-sectional view of the semiconductor storage device 1 according to the present embodiment.

In the following description, the stacking direction of a stack body 20 to be described later is defined as a Z direction. One direction intersecting, for example, orthogonal to the Z direction is defined as a Y direction. One direction orthogonal to the Z and Y directions is defined as an X direction.

As illustrated in FIG. 4, the memory chip 2 and the controller chip 3 are bonded to each other at a bonding surface B. The memory cell array included in the memory chip 2 and the peripheral circuit included in the controller chip 3 are electrically connected to each other through the bonding electrodes P1 and P2 joined to each other at the bonding surface B and through wires connected to the bonding electrodes P1 and P2. FIG. 4 illustrates a state in which the memory chip 2 is mounted on the upper surface of the controller chip 3.

The controller chip 3 includes a substrate 11, a processing circuit 12, vias 13, wires 14, the bonding electrodes P2, and an interlayer insulating film 15.

The substrate 11 is, for example, a semiconductor substrate such as silicon substrate. The processing circuit 12 includes a transistor provided on the substrate 11. The processing circuit 12 may include, in addition to the transistor, elements such as a resistance element and a capacitor element provided on the substrate 11.

The vias 13 electrically connect the processing circuit 12 and the wires 14 and electrically connect the wires 14 and the bonding electrodes P2. The wires 14 and the bonding electrodes P2 form a multi-layer wiring structure in the interlayer insulating film 15. The bonding electrodes P2 are embedded in the interlayer insulating film 15. At least a portion of a front surface of each bonding electrode P2 is exposed to be substantially flush with a front surface of the interlayer insulating film 15. The wires 14 and the bonding electrodes P2 are electrically connected to the processing circuit 12 and the like. The vias 13, the wires 14, and the bonding electrodes P2 are made of a low resistance metal such as copper or tungsten. The interlayer insulating film 15 covers and protects the processing circuit 12, the vias 13, and the wires 14. The interlayer insulating film 15 is an insulating film such as a silicon oxide film.

The memory chip 2 includes the stack body 20, column-shaped parts CL, slits ST, a source layer BSL, an interlayer insulating film 21, contacts 22, an insulating film 23, wires 24, and an insulating film 25.

The stack body 20 is provided above the processing circuit 12 and positioned in the Z direction relative to the substrate 11. The stack body 20 includes a plurality of electrode films 20a and a plurality of insulating films 20b that are alternately stacked in the Z direction. The electrode films 20a are made of a conductive metal such as tungsten. The insulating films 20b are made of, for example, silicon oxide. The insulating films 20b insulate the electrode films 20a from each other. In other words, the electrode films 20a are stacked in a mutually insulated state. The number of stacked electrode films 20a and the number of stacked insulating films 20b are optional. The insulating films 20b may be each, for example, a porous insulating film or an air gap.

In FIG. 4, 2s denotes a stepped part of the electrode films 20a, which is provided to connect contacts to the electrode films 20a. The memory chip 2 includes a source contact SC. The source contact SC has one end electrically connected to the source layer BSL, and the other end electrically connected to a bonding electrode P1.

One or a plurality of electrode films 20a at each of the upper and lower ends of the stack body 20 in the Z direction function as a source-side selection gate SGS or a drain-side selection gate SGD. At least a portion of electrode films 20a between the source-side selection gate SGS and the drain-side selection gate SGD function as word lines WL. Each word line WL is agate electrode of a memory cell MT. The drain-side selection gate SGD is a gate electrode of a drain-side selection transistor. The source-side selection gate SGS is a gate electrode of a source-side selection transistor. The source-side selection gate SGS is provided in an upper region of the stack body 20. The drain-side selection gate SGD is provided in a lower region of the stack body 20. The lower region is a region of the stack body 20 on a side closer to the controller chip 3, and the upper region is a region of the stack body 20 on a side farther from the controller chip 3 (side closer to the contacts 22 and the insulating film 25).

As described above, the semiconductor storage device 1 includes a plurality of memory cells MT connected in series between the source-side selection transistor ST2 and the drain-side selection transistor ST1. Each NAND string NS has a structure in which the source-side selection transistor ST2, the memory cells MT, and the drain-side selection transistor ST1 are connected in series. The NAND string NS is connected to a bit line BL through, for example, a via 26. The bit lines BL are a plurality of wires 27 provided below the stack body 20, each extending in the X direction, and provided alongside in the Y direction.

The plurality of column-shaped parts CL are provided in the stack body 20. In the stack body 20, the column-shaped parts CL extend and penetrate through the stack body 20 in the stacking direction of the stack body 20 (the Z direction) and are provided from the via 26 connected to the bit lines BL to the source layer BSL. In the present embodiment, each column-shaped part CL has a high aspect ratio and thus is formed as two divided parts in the Z direction. However, the column-shaped part CL may be a single part. The source-side selection transistor ST2 and the drain-side selection transistor ST1 include part of a column-shaped part CL.

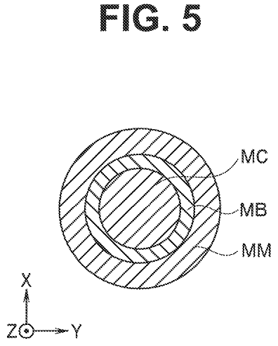

FIG. 5 is a schematic cross-sectional view of each column-shaped part CL at a memory cell MT part. Each of the plurality of column-shaped parts CL is provided in a memory hole MH provided in the stack body 20, which will be described later. Each of the plurality of column-shaped parts CL includes a semiconductor body MB, a memory film MM, and a core layer MC. Each column-shaped part CL includes the core layer MC provided at a central part, the semiconductor body (semiconductor member) MB provided around the core layer MC, and the memory film (electric charge accumulation member) MM provided around the semiconductor body MB.

The semiconductor body MB is electrically connected to the source layer BSL. The memory film MM is provided between the semiconductor body MB and each electrode film 20a and includes an electric charge capturing part. The shape of the memory hole MH on an XY plane is, for example, a circle or an ellipse.

As illustrated in FIG. 4, the source layer BSL is provided on an upper side of the stack body 20 through the interlayer insulating film 21. The source layer BSL includes a first surface F1, and a second surface F2 on a side opposite the first surface F1. The source layer BSL includes two layers, and a first layer BSL1 among the two layers is made of, for example, a conductive material such as doped polysilicon. A second layer BSL2 among the two layers is made of, for example, a conductive material such as tungsten. The stack body 20 is provided on the first surface F1 side of the source layer BSL, and the contacts 22, the insulating film 23, the wires 24, and the insulating film 25 are provided on the second surface F2 side.

The plurality of slits ST are provided in the stack body 20. The slits ST extend in the X direction and penetrate through the stack body 20 in the stacking direction of the stack body 20 (the Z direction). Each slit ST is filled with an insulation material such as silicon oxide, and the insulation material is formed in a plate shape. The stack body 20 is divided in the blocks BLK by the slits ST. The slits ST electrically divide the electrode films 20a of the stack body 20. The plurality of slits ST are formed such that one block BLK is sandwiched between two adjacent slits ST.

A plurality of string units SU are provided between two adjacent slits ST. In this example, the four string units SU0 to SU3 are provided between two adjacent slits ST as illustrated in FIG. 4.

A plurality of column-shaped parts CL (hereinafter referred to as dummy column-shaped parts CL) that are dummies and do not function as string units SU are formed in the X direction between two adjacent string units SU.

A slit SHE is provided in a lower region of each dummy column-shaped part CL. The slit SHE is formed from a lower surface of the stack body 20 to the drain-side selection gate SGD of the stack body 20. The slit SHE is formed by using, for example, a lithography technology and a reactive ion etching (RIE) method. The slit SHE is filled with an insulation material such as silicon oxide, and the insulation material is formed in a plate shape. The slit SHE extends in the X direction and has a function to separate the drain-side selection gates SGD of two adjacent string units.

A slit STA extends in the X direction and penetrates through the source layer BSL above a slit ST and an upper region of the slit ST. The slit STA is filled with an insulation material such as silicon oxide, and the insulation material is formed in a plate shape. The slit STA divides the source layer BSL in the Z direction. The slit STA is provided along the slit ST when the semiconductor storage device 1 is viewed in a direction orthogonal to an XY plane.

A slit STB extends in the X direction and penetrates through a source-side selection gate SGS part of each dummy column-shaped part CL at which the source layer BSL and the slit SHE are provided. The slit STB is filled with an insulation material such as silicon oxide, and the insulation material is formed in a plate shape. In other words, the slit STB is provided above the memory cell array 110 and formed to divide the upper region of the stack body 20 in which a plurality of source-side selection gates SGS are formed. The slit STB is provided along the slit SHE when the semiconductor storage device 1 is viewed in a direction orthogonal to an XY plane.

As described above, the slits ST extend in the X direction, electrically separate the stack body 20 of the memory cell array 110 for each block BLK, and are filled with an insulation material. The slits STA extend in the X direction, separate the region of the source layer BSL for each block BLK, and are filled with an insulation material. The slits STB extend in the X direction, separate the region of the source layer BSL and the region of the source-side selection gate SGS in the stack body 20 for each string unit SU in a block BLK, and are filled with an insulation material.

FIG. 4 illustrates a section of the semiconductor storage device 1 when viewed in the X direction, and only one column-shaped part CL and one via 26 are illustrated for each string unit SU in FIG. 4. In each string unit SU, a plurality of column-shaped parts CL and a plurality of vias 26 are disposed in the X direction.

Note that a plurality of column-shaped parts CL and a plurality of vias 26 in one string unit SU may be disposed in a staggered shape instead of being disposed along one line on an XY plane when the semiconductor storage device 1 is viewed from an upper surface. For example, in one string unit SU, a plurality of column-shaped parts CL and a plurality of vias 26 may be disposed in a staggered shape with four lines on an XY plane when the semiconductor storage device 1 is viewed from the upper surface.

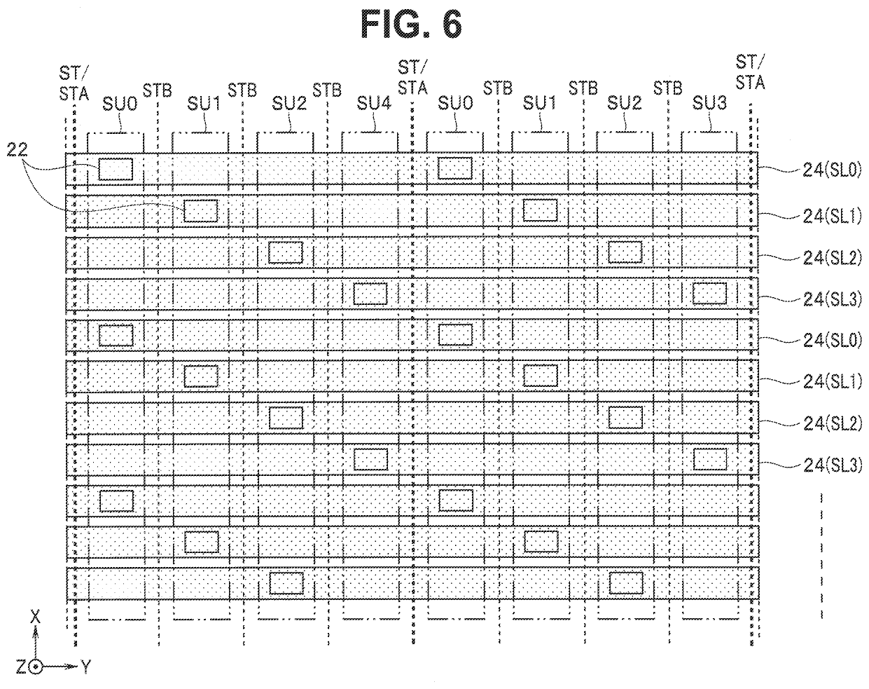

FIG. 6 is a diagram for description of the position of connection between each wire 24 as an upper layer wire and a source line SL of each string unit SU.

As described above, the source layer BSL in which the source line SL is formed is divided for each string unit SU by the slit STA, the slit STB, or the slits STA and STB. Thus, the source line SL of each string unit SU is electrically connected through contacts 22 at a predetermined interval in the X direction as illustrated in FIG. 6 so that a voltage is supplied as uniformly as possible to string units SU in one block BLK. Each wire 24 is formed in parallel to a bit line BL. In other words, an extending direction (the Y direction) of each wire 24 is the same as an extending direction of the bit line BL.

A desired source voltage can be independently supplied to each string unit SU by supplying a predetermined voltage to a wire 24. In other words, independent voltages different from each other can be supplied to a plurality of source lines SL of a plurality of string units SU.

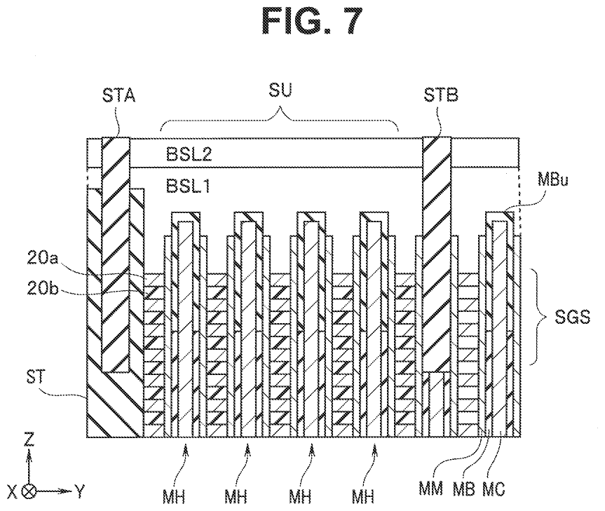

FIG. 7 is a partial cross-sectional view of the semiconductor storage device 1 in the Y direction. FIG. 7 illustrates sections of the source layer BSL and the upper region of the stack body 20. Note that FIG. 7 illustrates an example in which a plurality of column-shaped parts CL in one string unit SU are disposed in a staggered shape with four lines in the Y direction on an XY plane when the semiconductor storage device 1 is viewed from the upper surface. Thus, four column-shaped parts CL are illustrated for one string unit SU in the example illustrated in FIG. 7 when the semiconductor storage device 1 is viewed in the X direction.

In FIG. 7, an upper region MBu of each semiconductor body MB is a region in which phosphorus (P) is diffused. Note that the upper region MBu of each semiconductor body MB may contain a compound of nickel (Ni) and silicon (Si). Alternatively, the upper region MBu may include the interlayer insulating film 21 and a front surface of a slit ST and contain titanium nitride (TiN).

Similarly to the slits SHE, the slits STA and STB are formed by using the lithography technology and the RIE method.

As described above, the semiconductor storage device 1 includes the substrate 11, a circuit (the processing circuit 12) provided on the substrate 11, the plurality of bonding electrodes P2, the plurality of bonding electrodes P1, the memory cell array 110, and the slits STA and STB. The plurality of bonding electrodes P2 are provided above the substrate 11 and connected to the circuit (processing circuit 12) through a plurality of vias 13. The plurality of bonding electrodes P1 are connected to the plurality of bonding electrodes P2. The memory cell array 110 is connected to the plurality of bonding electrodes P1 through a plurality of vias 26. The memory cell array 110 includes a block BLK including a plurality of string units SU each including a plurality of memory cell transistors. Each string unit SU includes a plurality of column-shaped parts CL penetrating through the stack body 20 that is a stack of a plurality of electrode films 20a. The slits STA and STB divide, for each string unit SU, a source region SL of the plurality of memory cell transistors provided above the memory cell array 110 and a region of a plurality of selection gates SGS of the memory cell array.

### (Semiconductor Storage Device Manufacturing Method)

Subsequently, a method of manufacturing the semiconductor storage device 1 according to the present embodiment will be described below. (Memory chip manufacturing method)

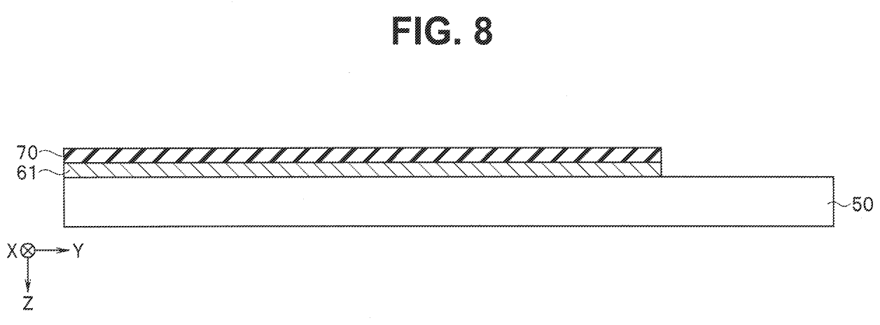

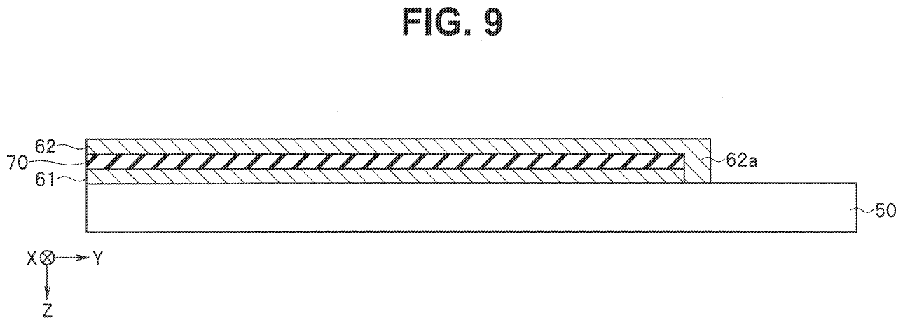

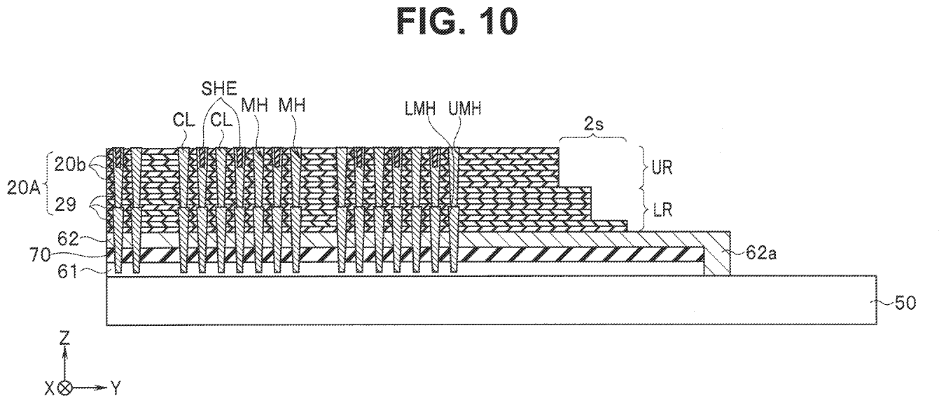

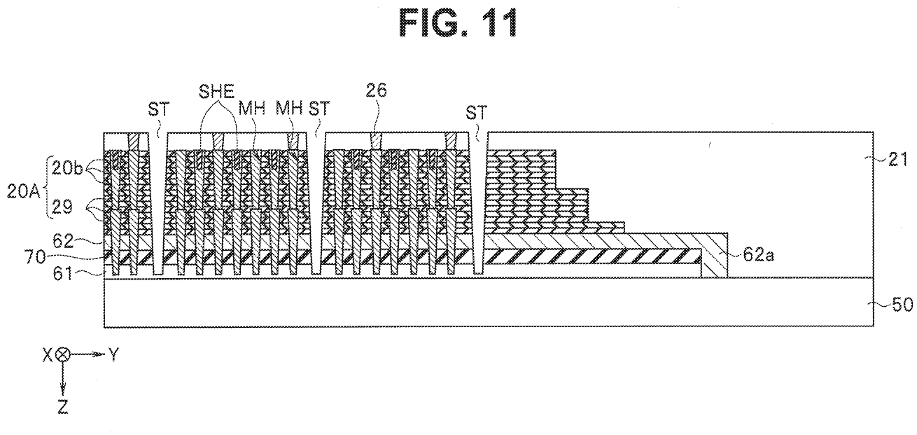

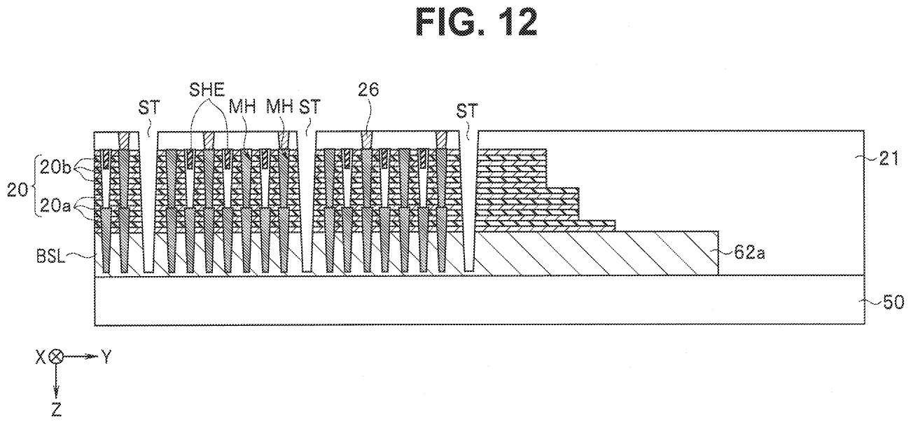

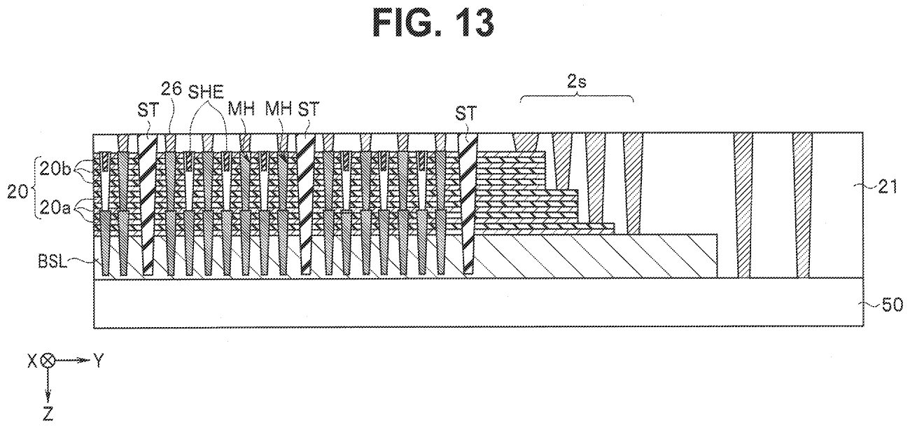

FIGS. 8 to 14 are cross-sectional views illustrating a method of manufacturing the memory chip 2 according to the present embodiment. FIG. 8 is a cross-sectional view illustrating a memory chip manufacturing method according to the first embodiment. FIG. 9 is a cross-sectional view illustrating the memory chip manufacturing method, following FIG. 8. FIG. 10 is a cross-sectional view illustrating the memory chip manufacturing method, following FIG. 9. FIG. 11 is a cross-sectional view illustrating the memory chip manufacturing method, following FIG. 10. FIG. 12 is a cross-sectional view illustrating the memory chip manufacturing method, following FIG. 11. FIG. 13 is a cross-sectional view illustrating the memory chip manufacturing method, following FIG. 12. FIG. 14 is a cross-sectional view illustrating the memory chip manufacturing method, following FIG. 13.

First, as illustrated in FIG. 8, a conductive film 61 is formed on a substrate 50 as a first substrate. A sacrifice film 70 is formed on the conductive film 61. The conductive film 61 is made of, for example, a conductive material such as doped polysilicon. The sacrifice film 70 is made of, for example, an insulating film such as a silicon nitride film. The conductive film 61 eventually remains as part of the source layer BSL. The sacrifice film 70 is eventually replaced with, for example, a conductive material such as doped polysilicon and thus is eventually removed.

Subsequently, part of the conductive film 61 and part of the sacrifice film 70 are removed by using the lithography technology and an etching technology so that the conductive film 61 and the sacrifice film 70 are left over at a formation position of the source layer BSL (lower side of the stack body 20).

Subsequently, as illustrated in FIG. 9, a conductive film 62 is deposited on the sacrifice film 70. The conductive film 62 is made of, for example, a conductive material such as doped polysilicon. Part of the conductive film 62 is removed by using the lithography technology and the etching technology so that the conductive film 62 covers on the sacrifice film 70 and side surfaces of the sacrifice film 70 and the conductive film 61. Accordingly, the conductive film 62 is left over on the sacrifice film 70, and a connection part 62a is left over at an end part (side part) of the sacrifice film 70. The conductive films 61 and 62 are electrically connected to each other through the connection part 62a and can function as an integrated conductive film.

Subsequently, as illustrated in FIG. 10, a plurality of insulating films (stacked insulating films) 20b and a plurality of sacrifice films 29 are alternately stacked above the conductive films 61 and 62. Each insulating film 20b is, for example, an insulating film such as a silicon oxide film. Each sacrifice film 29 is made of, for example, an insulating film such as a silicon nitride film, which can be etched with etching selectivity from the insulating films 20b. Note that a stack body of the insulating films 20b and the sacrifice films 29 is referred to as a stack body 20A below.

Subsequently, a stepped part 2s is formed by fabricating an end part of the stack body 20A into a stepped shape.

Subsequently, a plurality of memory holes MH penetrating through the stack body 20A in the stacking direction (Z direction) to the conductive films 61 and 62 are formed. The memory film MM, the semiconductor body MB, and the core layer MC described above are formed in each memory hole MH. Accordingly, a column-shaped part CL penetrating through the stack body 20A in the stacking direction is formed. The column-shaped part CL reaches the conductive films 61 and 62. Note that the memory hole MH and the column-shaped part CL are formed twice at upper and lower parts of the stack body 20A in the present embodiment. Note that the memory hole MH and the column-shaped part CL may be formed once for the stack body 20A.

A memory hole formed first is a memory hole (hereinafter referred to as a lower-layer memory hole) LMH formed in a lower layer of the stack body 20, and a memory hole formed next is a memory hole (hereinafter referred to as an upper-layer memory hole) UMH formed in an upper layer of the stack body 20. The stack body 20 has a lower layer region LR in which the lower-layer memory hole LMH is formed, and an upper layer region UR in which the upper-layer memory hole UMH is formed.

Subsequently, slits SHE are formed at a plurality of column-shaped parts CL (hereinafter referred to as dummy column-shaped parts) that do not function as string units SU. The slits SHE are formed by using the lithography technology and the RIE method. The slits SHE are filled with an insulation material such as silicon oxide.

Subsequently, as illustrated in FIG. 11, the interlayer insulating film 21 is formed on the stack body 20A. Subsequently, vias 26 are formed on the column-shaped parts CL, and slits ST are formed in the stack body 20A. The slits ST penetrate through the stack body 20A in the Z direction to the conductive films 61 and 62. The slits ST extend in the X direction and divide the stack body 20A for each block BLK as described above with reference to FIG. 4.

Subsequently, as illustrated in FIG. 12, the sacrifice film 70 is replaced with a conductive film through the slits ST. In other words, the sacrifice film 70 and part of the memory film MM in contact with the sacrifice film 70 are removed by etching, and a space in which the sacrifice film 70 and the part of the memory film MM in contact with the sacrifice film 70 have existed is filled with a material of the conductive film. The filling material of the conductive film may be the same as the material of the conductive films 61 and 62, and is, for example, a conductive material such as doped polysilicon. Accordingly, the conductive films 61 and 62 are integrated with the filling conductive film in place of the sacrifice film 70 and become the source layer BSL. The source layer BSL is electrically connected to each semiconductor body MB.

Subsequently, the sacrifice films 29 of the stack body 20A are replaced with the electrode films 20a through the slits ST. In other words, the sacrifice films 29 are removed by etching, and a space in which the sacrifice films 29 have existed is filled with a material of the electrode films 20a. The filling material of the electrode films 20a is, for example, a low resistance metal such as tungsten. Accordingly, the stack body 20 in which the plurality of electrode films 20a and the plurality of insulating films 20b are alternately stacked is formed.

Subsequently, as illustrated in FIG. 13, each slit ST is filled with an insulating film made of, for example, silicon oxide. Subsequently, contacts to be connected to, for example, the electrode films 20a (word lines WL, drain-side selection gates SGD, source-side selection gates SGS) at the stepped part 2s are formed.

Subsequently, as illustrated in FIG. 14, the wires 27 including bit lines BL, the bonding electrodes P1, and the like are formed on the interlayer insulating film 21 and in the interlayer insulating film 21, and accordingly, a multi-layer wiring structure is formed. The interlayer insulating film 21 in which the bonding electrodes P1 are embedded is polished by using a CMP method or the like until the bonding electrodes P1 are exposed. Accordingly, the bonding electrodes P1 are exposed in substantially flush on a front surface of the interlayer insulating film 21. This completes the memory chip 2 according to the present embodiment.

(Controller Chip Manufacturing Method)

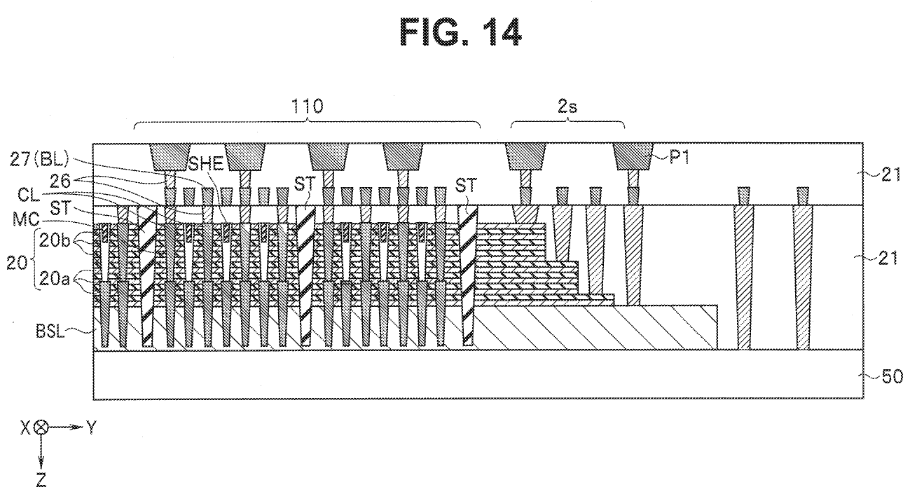

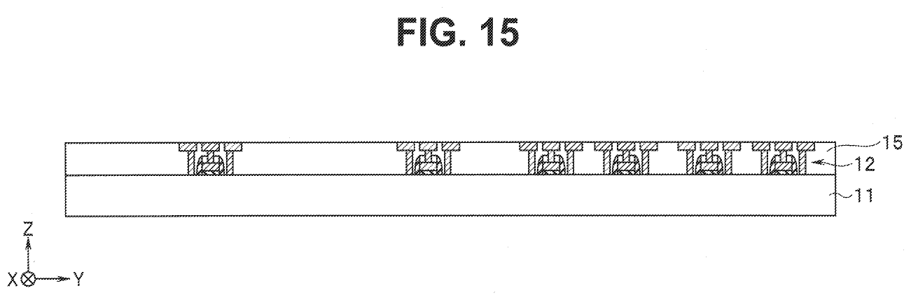

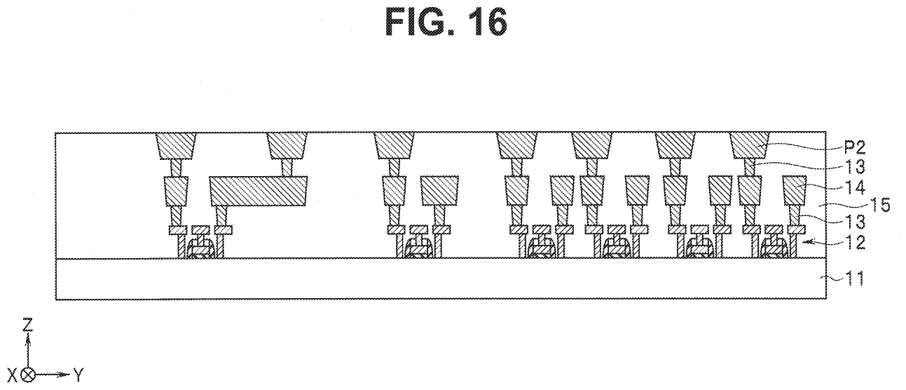

FIGS. 15 and 16 are cross-sectional views illustrating a method of manufacturing the controller chip 3 according to the first embodiment.

First, as illustrated in FIG. 15, the processing circuit 12 including a semiconductor element such as a transistor is formed on the substrate 11 as a second substrate. Subsequently, the processing circuit 12 is covered by the interlayer insulating film 15.

Subsequently, as illustrated in FIG. 16, the vias 13, the wires 14, and the bonding electrodes P2 are formed on the interlayer insulating film 15 and in the interlayer insulating film 15, and accordingly, a multi-layer wiring structure is formed. The interlayer insulating film 15 in which the bonding electrodes P2 are embedded is polished by using the CMP method or the like until the bonding electrodes P2 are exposed. Accordingly, the bonding electrodes P2 are exposed in substantially flush on the front surface of the interlayer insulating film 15. This completes the controller chip 3 according to the present embodiment.

(Bonding of Memory Chip and Controller Chip)

Subsequently, the memory chip 2 and the controller chip 3 are bonded to each other. Specifically, the memory chip 2 and the controller chip 3 are bonded such that the bonding electrodes P1 and P2 are in contact and electrically connected to each other, and the substrate 50 as the first substrate is removed.

Thereafter, as illustrated in FIG. 4, the slits STA and STB are formed. As described above, the slits STA penetrate through the source layer BSL and upper parts of the slits ST and divide the source layer BSL for each block BLK.

The slits STB penetrate through the source layer BSL and source-side selection gate SGS parts of the dummy column-shaped parts CL and each divide the source layer BSL and the source-side selection gates SGS of two adjacent string units SU for each string unit SU.

After the slits STA and STB are formed, the contacts 22, the insulating film 23, the wires 24, and the insulating film 25 are formed on the upper surface of the memory chip 2 and the bonding pad electrodes PX are lastly provided as illustrated in FIG. 4, and accordingly, the semiconductor storage device 1 illustrated in FIG. 4 is produced.

(Modification of Slit ST Formation Method)

The above-described slits ST penetrate through the stack body 20 in the stacking direction of the stack body 20 (the Z direction) and are filled with an insulation material, but some slits ST may have a structure including a plurality of column-shaped parts extending in the stacking direction of the stack body 20 (the Z direction). The plurality of column-shaped parts are disposed alongside in the X direction.

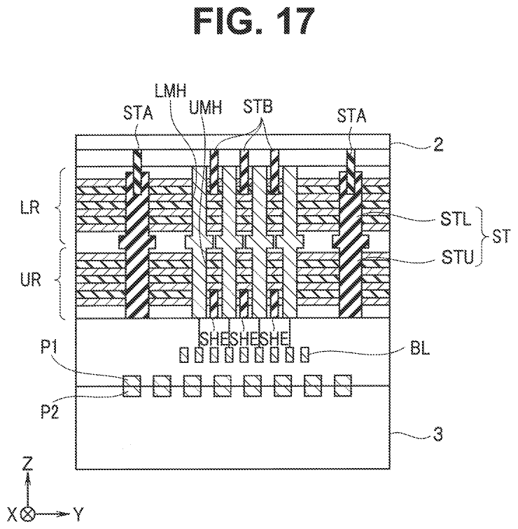

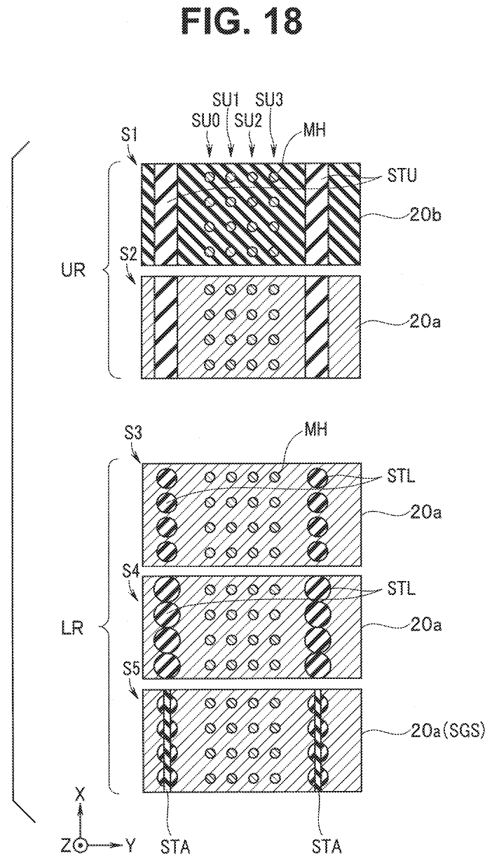

FIG. 17 is a schematic cross-sectional view of the semiconductor storage device 1 according to the present modification. FIG. 17 illustrates a section of the semiconductor storage device 1 along a YZ plane. FIG. 18 is a diagram for description of sectional shapes of slits ST along an XY plane in the upper layer region UR and the lower layer region LR according to the present modification.

In FIG. 17, the memory chip 2 is bonded to the controller chip 3, the upper layer region UR of the stack body 20 is positioned on the lower side, and the lower layer region LR is positioned on the upper side. FIG. 18 also illustrates a section of the stack body 20 along an XY plane. The four string units SU0 to SU3 are provided between two adjacent slits ST.

In FIG. 18, S1 denotes a section including the insulating films 20b in the upper layer region UR of the stack body 20, S2 denotes a section including the electrode films 20a in the upper layer region UR of the stack body 20, S3 and S4 denote sections including the electrode films 20a in the lower layer region LR of the stack body 20, and S5 denotes a section including the source-side selection gates SGS and the electrode films 20a in the lower layer region LR of the stack body 20.

First at formation of the stack body 20, the lower layer region LR including the lower-layer memory holes LMH is formed. Thereafter, the upper layer region UR including the upper-layer memory holes UMH is formed on the lower-layer memory holes LMH. In FIG. 17, the controller chip 3 is positioned on the upper layer region UR side of the stack body 20 of the memory chip 2.

As illustrated in FIG. 18, in the upper layer region UR, each slit ST includes a plate-shaped slit STU having a predetermined width in the Y direction and having a plate shape extending in the X direction. In the lower layer region LR, each slit ST includes a plurality of column-shaped parts STL having a circular section penetrating in the Z direction.

When each column-shaped part STL is formed, an inner diameter (illustrated in S3) of the column-shaped part STL at a deep part (upper part in FIG. 17) of the lower layer region LR of the stack body 20 is smaller than an inner diameter (illustrated in S4) of the column-shaped part STL at a shallow part (lower part in FIG. 17) near a front surface of the lower layer region LR. In FIG. 18, S3 denotes a section at a deep position in the lower layer region LR, and S4 denotes a section at a shallow position near the front surface of the lower layer region LR.

Thus, even when the plurality of column-shaped parts STL are formed in the X direction so that two adjacent column-shaped parts STL overlap, the two adjacent column-shaped parts STL are formed in separation from each other at a deep part in the lower layer region LR in some cases.

When two adjacent column-shaped parts STL are formed in separation from each other, a source-side selection gate SGS part at the deep part (upper part in FIG. 17) of the stack body 20 cannot be divided for block BLK.

Thus, in the present modification, the slits STA are provided through the plurality of column-shaped parts STL at the deep part (upper part in FIG. 17) of the stack body 20 as illustrated in FIG. 18 so that the source-side selection gate SGS part is reliably divided for each block BLK.

In other words, each slit ST includes a plate-shaped slit STU extending in the X direction in the upper layer region UR and includes a plurality of cylindrical column-shaped parts STL extending in the Z direction in the lower layer region LR. The slit ST also includes, in the lower layer region LR, a slit STA dividing a portion of the plurality of column-shaped parts STL in the X direction to divide the source-side selection gate SGS part for each block BLK. Note that FIG. 18 exemplarily illustrates a case in which the inner diameter of each column-shaped part STL is larger than each memory hole MH at any of a deep part (part illustrated in S3) in the lower layer region LR, a shallow part (part illustrated in S4) near the front surface of the lower layer region LR, and a part (part illustrated in S5) including the source-side selection gates SGS. However, the inner diameter of each column-shaped part STL may be substantially equal to or smaller than each memory hole MH at at least either of the deep part (part illustrated in S3) in the lower layer region LR, the shallow part (part illustrated in S4) near the front surface of the lower layer region LR, and the part (part illustrated in S5) including the source-side selection gates SGS.

Subsequently, a semiconductor storage device manufacturing method according to the modification will be described below.

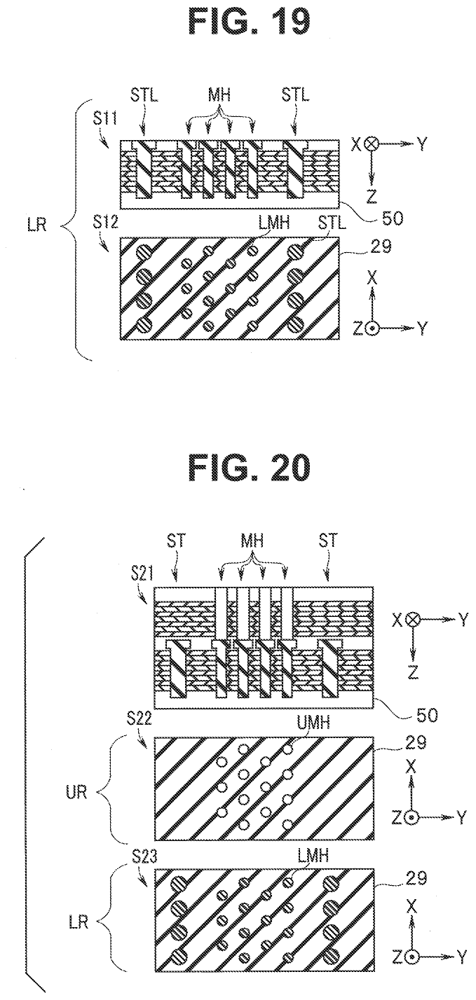

FIG. 19 is a schematic diagram illustrating the lower layer region LR of the stack body 20. In FIG. 19, S11 denotes a section of the lower layer region LR of the memory chip 2 along a YZ plane, and S12 denotes a section of the lower layer region LR along an XY plane.

First, the lower layer region LR is formed on the substrate 50. Each lower-layer memory hole LMH is formed by using the lithography technology and the RIE method. Each lower-layer memory hole LMH is filled with an insulation material used as a sacrifice film. After the lower layer region LR is formed, the upper layer region UR is formed.

FIG. 20 is a schematic diagram of the memory chip in a state in which the memory holes MH in the upper layer region UR are formed above the lower layer region LR. In FIG. 20, S21 denotes a section of the memory chip 2 along a YZ plane, S22 denotes a section of the upper layer region UR along an XY plane, and S23 denotes a section of the lower layer region LR along an XY plane. As illustrated in FIG. 20, the upper-layer memory holes UMH are formed in the upper layer region UR. Each upper-layer memory hole UMH is formed by using the lithography technology and the RIE method.

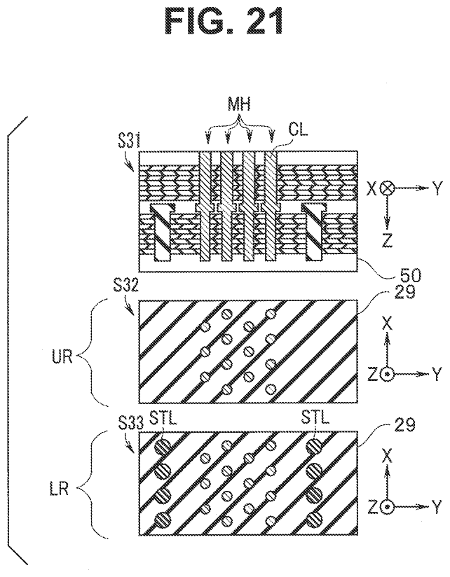

FIG. 21 is a schematic diagram of the memory chip in a state in which the plurality of column-shaped parts CL are formed. In FIG. 21, S31 denotes a section of the memory chip 2 along a YZ plane, S32 denotes a section of the upper layer region UR along an XY plane, and S33 denotes a section of the lower layer region LR along an XY plane. FIG. 21 illustrates a state in which the plurality of column-shaped parts CL each including the semiconductor body MB (not illustrated in FIG. 21), the memory film MM (not illustrated in FIG. 21), and the core layer MC (not illustrated in FIG. 21) are formed in the upper-layer memory holes UMH and the lower-layer memory holes LMH. After an insulation material filling each lower-layer memory hole LMH is removed, the column-shaped parts CL are formed in the upper-layer memory holes UMH and the lower-layer memory holes LMH.

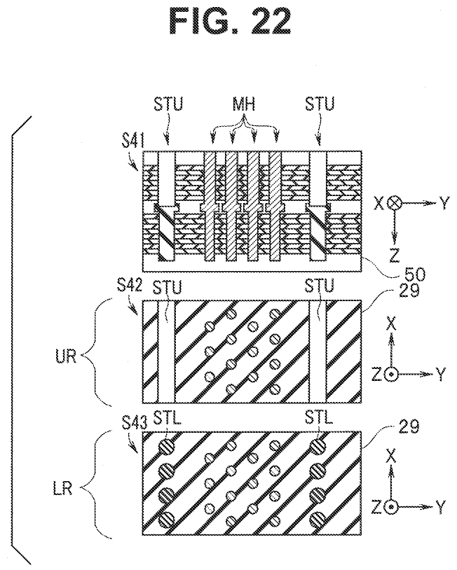

FIG. 22 is a schematic cross-sectional view of the memory chip in a state in which openings of the plate-shaped slits STU are formed in the upper layer region UR. In FIG. 22, S41 denotes a section of the memory chip 2 along a YZ plane, S42 denotes a section of the upper layer region UR along an XY plane, and S43 denotes a section of the lower layer region LR along an XY plane. Openings for the plate-shaped slits STU are formed in the upper layer region UR.

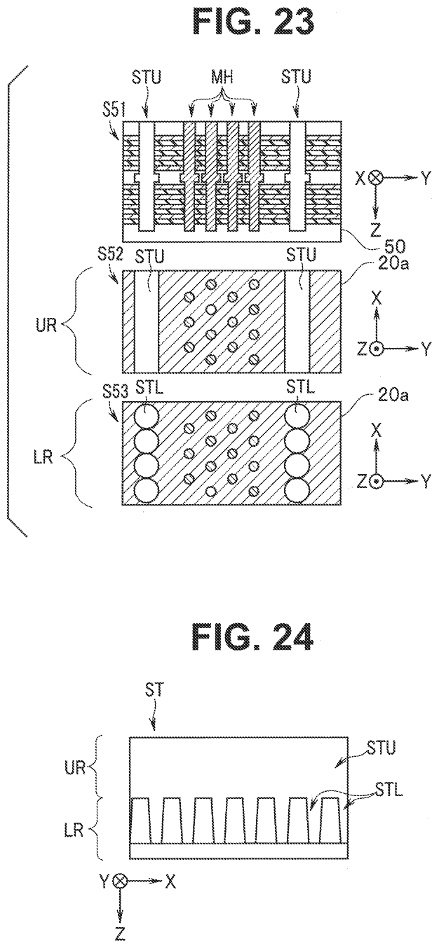

FIG. 23 is a schematic cross-sectional view of the memory chip in a state in which the sacrifice films are replaced with a conductive material. In FIG. 23, S51 denotes a section of the memory chip 2 along a YZ plane, S52 denotes a section of the upper layer region UR along an XY plane, and S53 denotes a section of the lower layer region LR along an XY plane.

The sacrifice films 29 are replaced with a conductive film through the openings for the plate-shaped slits STU. In other words, the sacrifice films 29 is removed by etching, and a space in which the sacrifice films 29 have existed is filled with a material of the conductive film. Note that the removal of the sacrifice films 29 is performed after the insulation material as a sacrifice film filling each lower-layer memory hole LMH is removed.

FIG. 24 is a schematic diagram for description of a sectional shape of each slit ST along an XZ plane. FIG. 24 illustrates only the shape of the slit ST. As illustrated in FIG. 24, the openings for the plate-shaped slits STU communicate with each other in the X direction, and the plurality of column-shaped parts STL are each formed with an inner diameter that is smaller at a lower part. In other words, as illustrated in FIG. 24, the inner diameter of each of the plurality of column-shaped parts STL on the lower side (lower side in FIG. 24) in the lower layer region LR is smaller than the inner diameter of each column-shaped part STL on the upper side (upper side in FIG. 24) in the lower layer region LR.

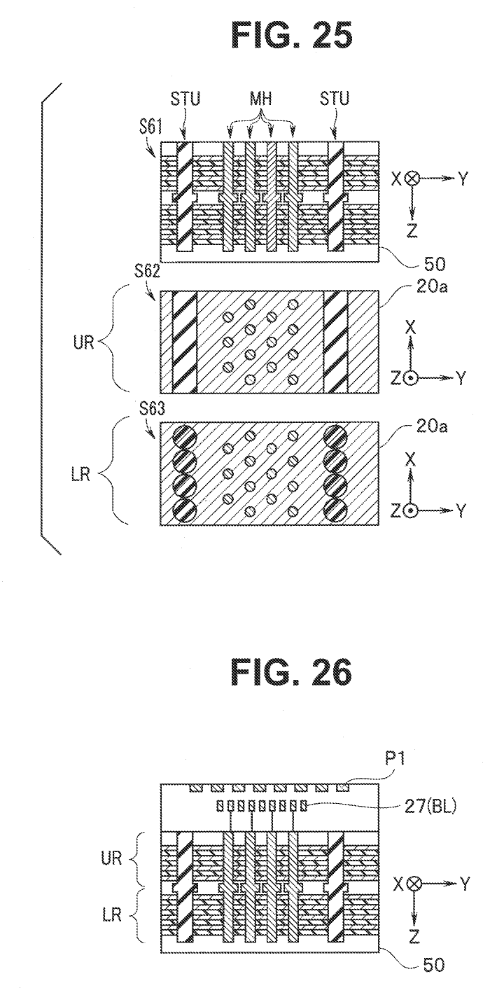

FIG. 25 is a schematic cross-sectional view of the memory chip 2 in a state in which an insulation material is embedded in the slits ST. In FIG. 25, S61 denotes a section of the upper layer region UR along a YZ plane, S52 denotes a section of the upper layer region UR along an XY plane, and S53 denotes a section of the lower layer region LR along an XY plane.

Subsequently, the bit lines BL, the bonding electrodes P1, and the like are formed on the upper layer region UR. FIG. 26 is a schematic cross-sectional view of the memory chip 2 in a state in which the bonding electrodes P1 are formed on the front surface of the memory chip 2.

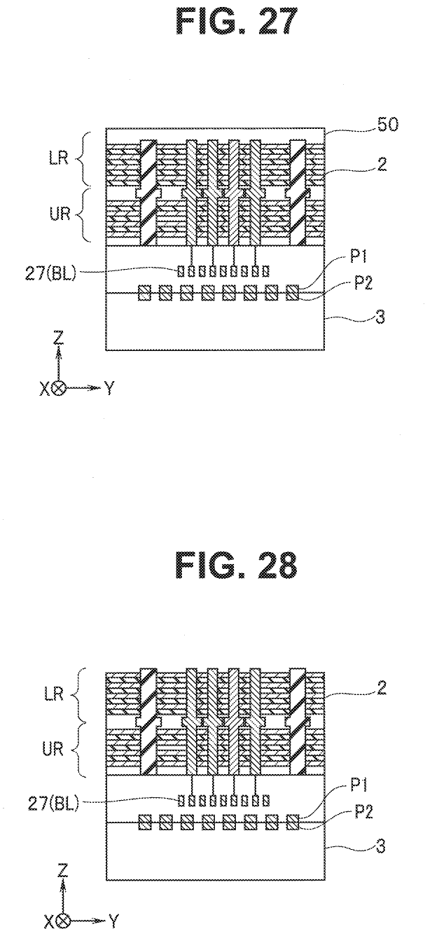

Subsequently, the front surface of the controller chip 3 and the front surface of the memory chip 2, which are separately produced, are bonded to each other. FIG. 27 is a schematic cross-sectional view of the semiconductor storage device in a state in which the memory chip 2 and the controller chip 3 are bonded to each other.

Subsequently, the substrate 50 of the memory chip 2 is removed. FIG. 28 is a schematic cross-sectional view of the semiconductor storage device in a state in which the memory chip 2 from which the substrate 50 of the memory chip 2 is removed and the controller chip 3 are bonded to each other.

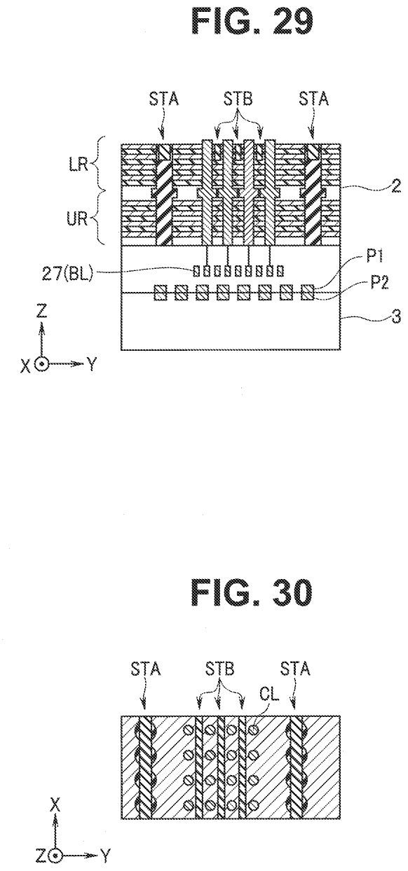

Then, at each slit ST part, a slit STA containing an insulation material is formed in the Z direction to a depth of an SGS part of a memory hole MH. FIG. 29 is a schematic cross-sectional view of the semiconductor storage device in a state in which the memory chip 2 in which the slits STA and STB are formed and the controller chip 3 are bonded to each other.

FIG. 30 is a plan view of the memory chip 2 from a back surface side of the memory chip 2 in which the slits STA and STB are formed. As illustrated in FIG. 30, the plurality of column-shaped parts CL are formed in the X direction, and the slits STA are formed from a back side of the memory chip 2 to the source-side selection gate SGS parts of the plurality of column-shaped parts CL, and accordingly, the source-side selection gate SGS parts are divided for each block BLK.

As described above in the modification, the slits ST may be formed.

In the semiconductor storage device according to the above-described embodiment, the source layer BSL is divided between two adjacent string units SU, and the source-side selection gate SGS is divided between two adjacent string units SU.

Since the source-side selection gate SGS is divided for string unit SU, voltages supplied to a plurality of source-side selection gates SGS can be differentiated from each other. Thus, when a reading or writing voltage is supplied to a selection word line WL, a voltage of the source-side selection gate SGS or the source layer BSL of the non-selected string unit SU is controlled to put any non-selected string unit SU into a floating state, and accordingly, a voltage of a channel of the non-selected string unit in the floating state increases due to coupling between the channel of the non-selected string unit and the selection word line WL. As a result, it is possible to perform data writing and reading at high speed. Moreover, it is possible to improve program disturbance and read disturbance.

### Second Embodiment

In the above-described first embodiment, the source layer BSL and each source-side selection gate SGS part are both divided between two adjacent string units SU. However, in the second embodiment, the source layer BSL may not be divided between two adjacent string units SU and each source-side selection gate SGS part may be divided between two adjacent string units SU. In the second embodiment, the source layer BSL is not divided between two adjacent string units SU, and each source-side selection gate SGS part is divided between two adjacent string units SU.

A configuration of a semiconductor storage device 1A according to the second embodiment is substantially the same as the configuration of the semiconductor storage device 1 according to the first embodiment, and thus in description below, any same constituent component in the semiconductor storage device 1A according to the second embodiment as in the semiconductor storage device 1 according to the first embodiment is denoted by, for example, the same number or reference sign, description of the constituent component is omitted, and any configuration different from in the semiconductor storage device 1 will be described.

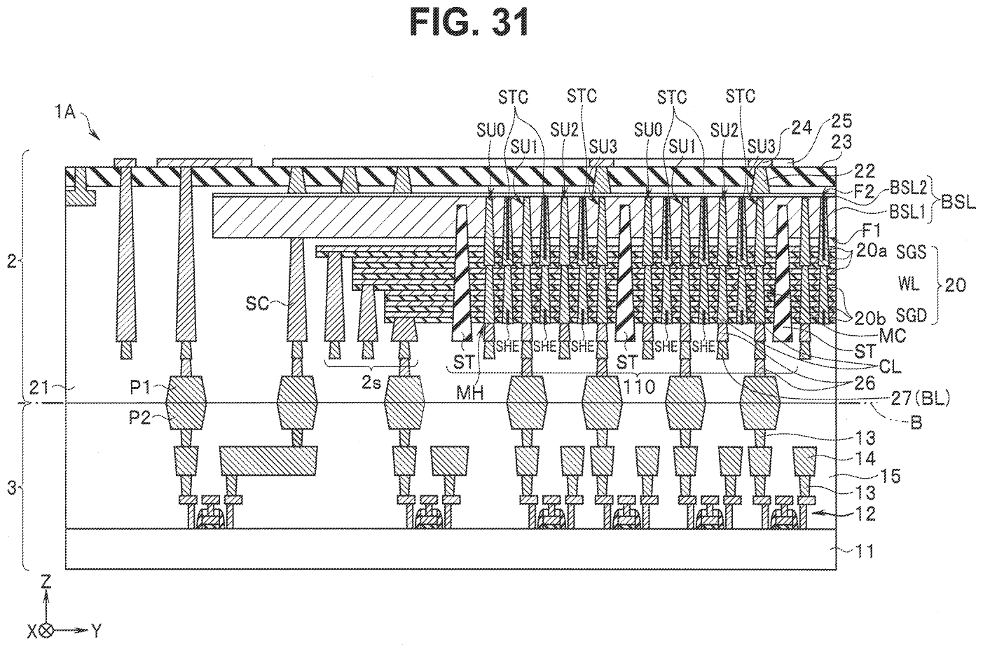

FIG. 31 is a cross-sectional view of the semiconductor storage device 1A according to the present embodiment. As illustrated in FIG. 31, slits STC are provided such that the slits STC extend in the X direction and penetrate through a portion of the source layer BSL and the source-side selection gate SGS parts of a plurality of dummy column-shaped parts CL provided with slits SHE. The slits STC are filled with an insulation material such as silicon oxide, and the insulation material filling the slits STC is formed in a plate shape. Each slit STC is provided along a slit SHE when the semiconductor storage device 1 is viewed in a direction orthogonal to an XY plane.

As illustrated in FIG. 31, the plurality of slits STC are provided above the memory cell array 110 and divide, for string unit SU, the upper region of the stack body 20 including a plurality of source-side selection gates SGS.

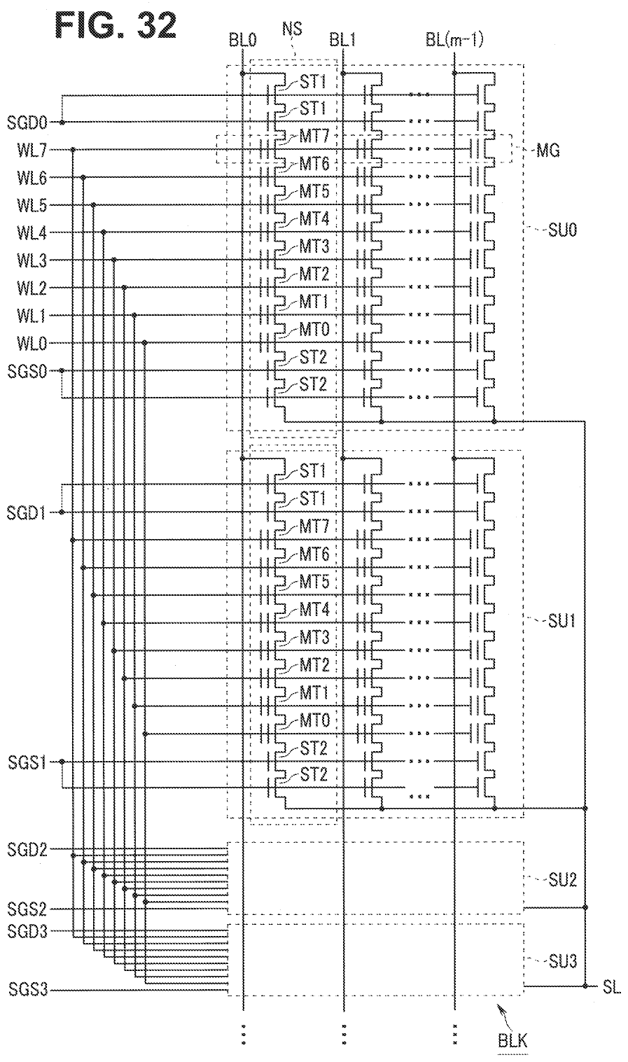

FIG. 32 is a diagram illustrating a configuration of one block BLK of the memory cell array 110 having a three-dimensional structure according to the present embodiment.

The gates of the selection transistors ST1 of the string units SU0 to SU3 are connected to the selection gate lines SGD0 to SGD3, respectively. Voltages of the selection gate lines SGD0 to SGD3 can be each independently controlled by the sequencer 170.

The gates of the selection transistors ST2 of the string units SU0 to SU3 are connected to the selection gate lines SGS0 to SGS3, respectively. Voltages of the selection gate lines SGS0 to SGS3 can be each independently controlled by the sequencer 170.

The sources of the selection transistors ST2 of the string units SU0 to SU3 are connected in common to the source line SL.

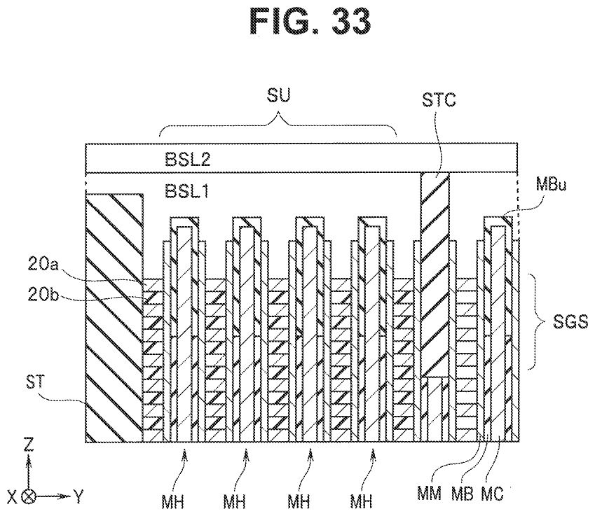

FIG. 33 is a partial cross-sectional view of the semiconductor storage device 1A in the Y direction. FIG. 33 illustrates sections of the source layer BSL and the upper region of the stack body 20.

In the present embodiment, each source-side selection gate SGS part is divided between two adjacent string units SU by a slit STC. However, part of the source layer BSL, for example, the first layer BSL1 is divided between two adjacent string units SU, but the other part of the source layer BSL, for example, the second layer BSL2 is electrically connected between two adjacent string units SU.

Thus, according to the present embodiment as well, it is possible to float (in other words, boost) any non-selected string unit SU and perform data writing and reading at high speed.

### Third Embodiment

In the above-described first embodiment, the source layer BSL and each source-side selection gate SGS part are both divided between two adjacent string units SU. However, in the third embodiment, each source-side selection gate SGS part may not be divided between two adjacent string units SU and the source layer BSL may be divided between two adjacent string units SU. In the third embodiment, each source-side selection gate SGS part is not divided between two adjacent string units SU, and the source layer BSL is divided between two adjacent string units SU.

A configuration of a semiconductor storage device 1B according to the third embodiment is substantially the same as the configuration of the semiconductor storage device 1 according to the first embodiment, and thus in description below, any same constituent component in the semiconductor storage device 1B according to the third embodiment as in the semiconductor storage device 1 according to the first embodiment is denoted by, for example, the same number or reference sign, description of the constituent component is omitted, and any configuration different from in the semiconductor storage device 1 will be described.

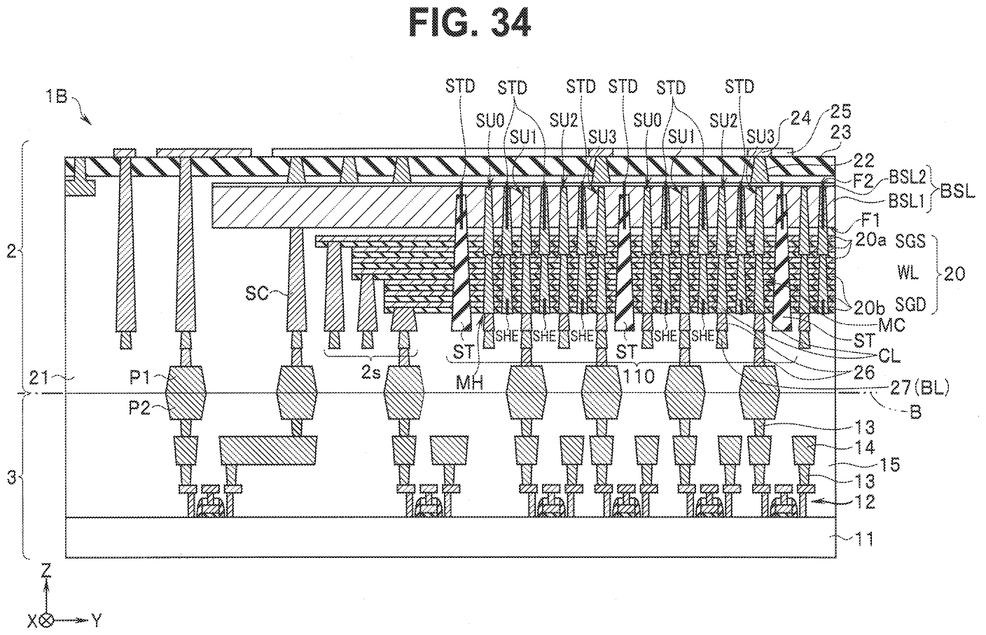

FIG. 34 is a cross-sectional view of the semiconductor storage device 1B according to the present embodiment. As illustrated in FIG. 34, slits STD are provided such that the slits STD extend in the X direction and penetrate through the source layer BSL. The slits STD are filled with an insulation material such as silicon oxide and each formed in a plate shape. Each slit STD is provided along a slit ST and a slit SHE when the semiconductor storage device 1 is viewed in a direction orthogonal to an XY plane.

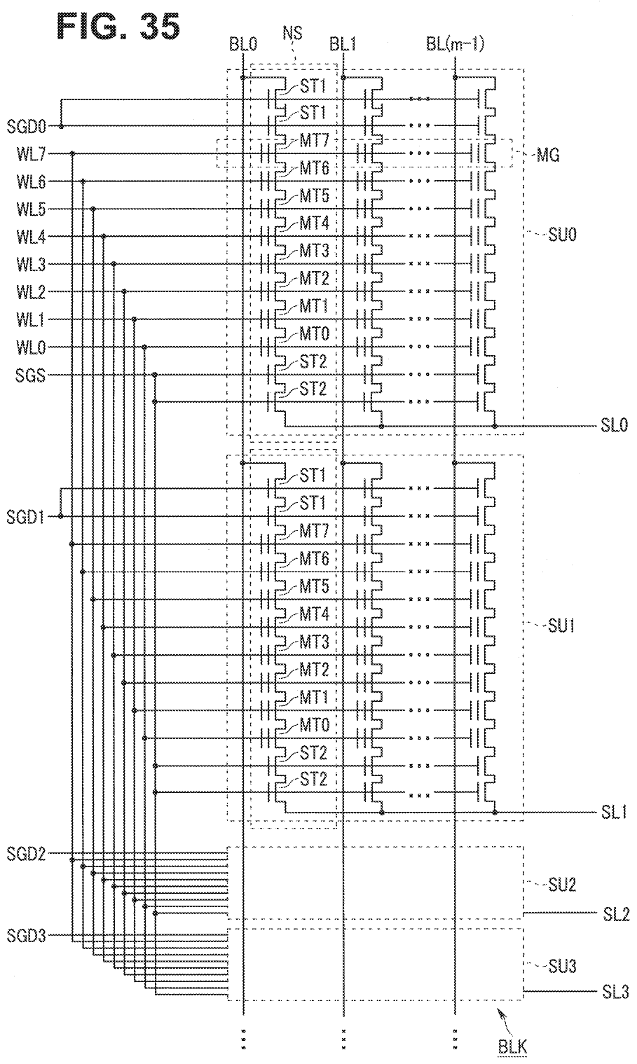

FIG. 35 is a diagram illustrating a configuration of one block BLK of the memory cell array 110 having a three-dimensional structure according to the present embodiment.

The gates of the selection transistors ST1 of the string units SU0 to SU3 are connected to the selection gate lines SGD0 to SGD3, respectively. Voltages of the selection gate lines SGD0 to SGD3 can be each independently controlled by the sequencer 170.

The gates of the selection transistors ST2 of the string units SU0 to SU3 are connected in common to a selection gate line SGS.

The sources of the selection transistors ST2 of the string units SU0 to SU3 are connected to the source lines SL0 to SL3, respectively. Voltages of the source lines SL0 to SL3 can be each independently controlled by the sequencer 170.

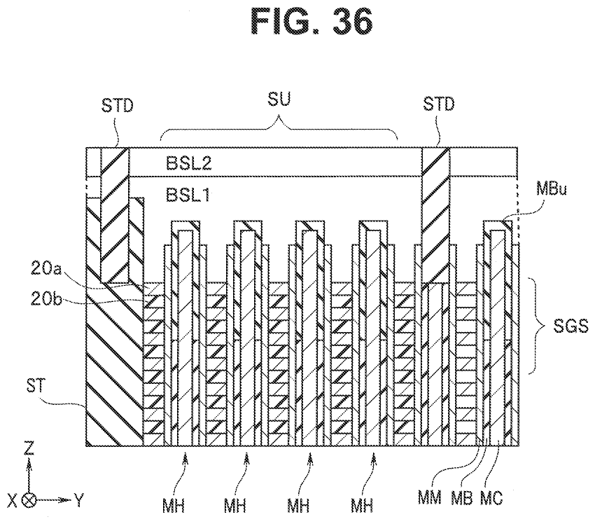

FIG. 36 is a partial cross-sectional view of the semiconductor storage device 1B in the Y direction. FIG. 36 illustrates sections of the source layer BSL and the upper region of the stack body 20.

In the present embodiment, the source layer BSL is divided between two adjacent string units SU by a slit STD.

Thus, according to the present embodiment as well, it is possible to float (in other words, boost) any non-selected string unit SU and perform data writing and reading at high speed.

While certain embodiments have been described, these embodiments have been presented by way of example only, and are not intended to limit the scope of the inventions. Indeed, the novel devices and systems described herein may be embodied in a variety of other forms; furthermore, various omissions, substitutions and changes in the form of the devices and systems described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a substrate;
a circuit provided on the substrate;
a plurality of first electrodes provided above the substrate and connected to the circuit through a plurality of first contacts;
a plurality of second electrodes connected to the plurality of first electrodes;
a memory cell array connected to the plurality of second electrodes through a plurality of second contacts, the memory cell array including a block, the block including a plurality of units, each of the units including a plurality of memory cell transistors and a plurality of first column-shaped parts, the plurality of first column-shaped parts penetrating through at least one stack body that is a stack of a plurality of electrode layers between which an insulating layer is interposed;
a first source region provided above the memory cell array and electrically connected to a portion of the plurality of memory cell transistors;
a second source region provided above the memory cell array and electrically connected to another portion of the plurality of memory cell transistors; and
a first slit insulating the first source region and the second source region for each of the units.

2. The semiconductor storage device according to claim 1, wherein a first voltage can be supplied to the first source region, and a second voltage different from the first voltage can be supplied to the second source region.

3. The semiconductor storage device according to claim 1, further comprising:
a plurality of first selection gates provided in the stack body of the plurality of electrode layers and used to select the plurality of units in the block; and
a second slit dividing, for each of the units, an upper region of the stack body including the plurality of first selection gates.

4. The semiconductor storage device according to claim 3, wherein a third voltage can be supplied to a portion of the plurality of first selection gates, and a fourth voltage different from the third voltage can be supplied to another portion of the plurality of first selection gates.

5. The semiconductor storage device according to claim 3, wherein an upper end of the second slit is connected to a lower end of the first slit.

6. The semiconductor storage device according to claim 3, further comprising:
a plurality of second selection gates provided in the stack body of the plurality of electrode layers and used to select the plurality of units in the block; and
a third slit dividing, for each of the units, a lower region of the stack body including the plurality of second selection gates,
wherein the third slit is formed vertically below the second slit.

7. The semiconductor storage device according to claim 6, wherein a fifth voltage can be supplied to a portion of the plurality of second selection gates, and a sixth voltage different from the fifth voltage can be supplied to another portion of the plurality of second selection gates.

8. The semiconductor storage device according to claim 3, further comprising a plurality of second column-shaped parts disposed between one of the blocks and a portion of another of the blocks and filled with an insulation material, wherein a fourth slit is formed in an array direction of the plurality of second column-shaped parts in an upper region of each of the second column-shaped parts and filled with an insulation material.

9. The semiconductor storage device according to claim 8, further comprising a fifth slit insulating the first source region and the second source region for each of the blocks and having a lower end connected to an upper end of the fourth slit.

10. The semiconductor storage device according to claim 8, further comprising a sixth slit formed in the array direction of the plurality of second column-shaped parts between one of the blocks and a portion of another of the blocks, filled with an insulation material, and having an upper end connected to lower ends of the plurality of second column-shaped parts.

11. The semiconductor storage device according to claim 8, wherein a height of each of the second column-shaped parts is lower than a height of each of the first column-shaped parts, and a sixth slit formed in the array direction of the plurality of second column-shaped parts and filled with an insulation material is formed between a bottom surface of the second column-shaped part and a lower surface height of the first column-shaped part.

12. A semiconductor storage device comprising:
a substrate;
a circuit provided on the substrate;
a plurality of first electrodes provided above the substrate and connected to the circuit through a first contact;
a plurality of second electrodes connected to the plurality of first electrodes;
a memory cell array connected to the plurality of second electrodes through a plurality of second contacts, the memory cell array including a block, the block including a plurality of units, each of the units including a plurality of memory cell transistors and a plurality of first column-shaped parts, the plurality of first column-shaped parts penetrating through at least one stack body that is a stack of a plurality of electrode layers between which an insulating layer is interposed; and
a slit dividing, for each of the units, an upper region of the stack body including a plurality of first selection gates used to select the plurality of units in the block.

13. The semiconductor storage device according to claim 12, wherein a seventh voltage can be supplied to a portion of the plurality of first selection gates, and an eighth voltage different from the seventh voltage can be supplied to another portion of the plurality of first selection gates.

14. The semiconductor storage device according to claim 12, further comprising:
a plurality of second selection gates provided in the stack body of the plurality of electrode layers and used to select the plurality of units in the block; and
a third slit dividing, for each of the units, a lower region of the stack body including the plurality of second selection gates,
wherein the third slit is formed vertically below the slit.

15. The semiconductor storage device according to claim 14, wherein a ninth voltage can be supplied to a portion of the plurality of second selection gates, and a tenth voltage different from the ninth voltage can be supplied to another portion of the plurality of second selection gates.

16. The semiconductor storage device according to claim 12, further comprising a plurality of second column-shaped parts disposed between one of the blocks and a portion of another of the blocks and filled with an insulation material, wherein a coupling slit is formed in an array direction of the plurality of second column-shaped parts in an upper region of each of the second column-shaped parts and filled with an insulation material.

17. The semiconductor storage device according to claim 16, further comprising a sixth slit formed in the array direction of the plurality of second column-shaped parts between one of the blocks and a portion of another of the blocks, filled with an insulation material, and having an upper end connected to lower ends of the plurality of second column-shaped parts.

18. The semiconductor storage device according to claim 16, wherein a height of each of the second column-shaped parts is lower than a height of each of the first column-shaped parts, and a sixth slit formed in the array direction of the plurality of second column-shaped parts and filled with an insulation material is formed between a bottom surface of the second column-shaped part and a lower surface height of the first column-shaped part.

19. A semiconductor storage device manufacturing method comprising:
forming a first semiconductor chip including a plurality of first electrodes and a first substrate including a circuit;
forming a second semiconductor chip in which a memory cell array, a plurality of second column-shaped parts, and a plurality of second electrodes are formed on a second substrate, the memory cell array including a plurality of blocks, each of the blocks including a plurality of units, each of the units including a plurality of memory cell transistors and a plurality of first column-shaped parts, the plurality of first column-shaped parts penetrating through at least one stack body that is a stack of a plurality of electrode layers between which an insulating layer is interposed, each of the plurality of second column-shaped parts including an insulation material and disposed between the blocks;
bonding the first semiconductor chip and the second semiconductor chip by connecting the plurality of first electrodes and the plurality of second electrodes, respectively;
forming a slit in an array direction of the plurality of second column-shaped parts from a side of the second semiconductor chip bonded to the first semiconductor chip to a portion of the plurality of second column-shaped parts, the side being opposite the first semiconductor chip; and
filling the slit with an insulation material.

20. The semiconductor storage device manufacturing method according to claim 19, further comprising:
forming a second slit dividing, for each of the units, an upper region of the stack body including a plurality of selection gates used to select the plurality of units in the block; and
filling the second slit with an insulation material.
